(19) United States
(12) Patent Application Publication
(10) Pub. No.: US 2026/0369527 A1
(43) Pub. Date: Nov. 19, 2026

(54) SYSTEMS AND METHODS FOR CONTROLLING AN LF RF PULSE GENERATOR TO INCREASE SELECTIVITY

(71) Applicant: Lam Research Corporation, Fremont, CA (US)

(72) Inventors: Alexei M. Marakhtanov, Albany, CA (US); Lim Zhao, Fremont, CA (US); Fabio Righetti, Redwood City, CA (US); Kenneth Lucchesi, Newark, CA (US); John P. Holland, San Jose, CA (US)

(21) Appl. No.: 19/138,084

(22) PCT Filed: Dec. 7, 2023
(86) PCT No.: PCT/US2023/083011

§ 371 Date: Jun. 11, 2025

Related U.S. Application Data
(60) Provisional application No. 63/432,472, filed on Dec. 14, 2022.

(51) Int. Cl. H01J 37/32; H03K 3/36

(52) U.S. Cl. CPC H01J 37/32174; H03K 3/36; H01J 2237/334

(57) ABSTRACT

Systems and methods for controlling a low frequency (LF) radio frequency (RF) pulse generator to increase selectivity are described. One of the methods includes controlling the LF RF pulse generator to generate a plurality of square pulses that are interspersed with a plurality of square sub-pulses. Each of the plurality of square pulses has a first sub-pulse width that is greater than a second sub-pulse width of each of the plurality of square sub-pulses.

### FIELD

The present embodiments relate to systems and methods for controlling a low frequency (LF) radio frequency (RF) pulse generator to increase selectivity.

### BACKGROUND

In a plasma tool, there are multiple radio frequency (RF) generators. The RF generators are coupled via a match to a plasma chamber. A wafer is placed inside the plasma chamber for processing. The RF generators generate RF signals and supply the RF signals to the match. The match matches an output impedance with an input impedance to output an RF signal towards the plasma chamber. The RF signal is used to generate plasma for processing the wafer. However, it is difficult to etch a desired layer of the wafer while maintaining a mask layer of the wafer.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for controlling a low frequency (LF) radio frequency (RF) generator to increase selectivity. It should be appreciated that the present embodiments can be implemented in numerous ways, e.g., a process, an apparatus, a system, a device, or a method on a computer readable medium. Several embodiments are described below.

In an embodiment, sub-pulses are introduced between peaks of pulses to produce ions with lower energy. The low energy ions improve mask selectivity.

In one embodiment, a method for controlling an LF RF pulse generator to increase selectivity is described. The method includes controlling the LF RF pulse generator to generate a plurality of square pulses that are interspersed with a plurality of square sub-pulses. Each of the plurality of square pulses has a first sub-pulse width that is greater than a second sub-pulse width of each of the plurality of square sub-pulses. The operation of controlling the LF RF pulse generator includes controlling the LF RF pulse generator to generate one of the plurality of square pulses, determining whether a predetermined amount of time has passed since controlling the LF RF pulse generator to generate the one of the plurality of square pulses, and controlling the LF RF pulse generator to generate one of the plurality of square sub-pulses upon determining that the predetermined amount of time has passed. The operation of controlling the LF RF pulse generator to generate the plurality of square sub-pulses increases the selectivity.

In an embodiment, a controller for controlling an LF RF pulse generator to increase selectivity is described. The controller includes a processor that controls the LF RF pulse generator to generate a plurality of square pulses that are interspersed with a plurality of square sub-pulses. Each of the plurality of square pulses has a first sub-pulse width that is greater than a second sub-pulse width of each of the plurality of square sub-pulses. To control the LF RF pulse generator, the processor controls the LF RF pulse generator to generate one of the plurality of square pulses. Moreover, to control the LF RF pulse generator, the processor determines whether a predetermined amount of time has passed since the LF RF pulse generator is controlled to generate the one of the plurality of square pulses. Also, to control the LF RF pulse generator, the processor controls the LF RF pulse generator to generate one of the plurality of square sub-pulses upon determining that the predetermined amount of time has passed. The controller includes a memory device coupled to the processor.

In one embodiment, a plasma system is described. The plasma system includes an LF RF pulse generator. The plasma system further includes a plasma chamber coupled to the LF RF pulse generator via an RF cable. The plasma system includes a controller coupled to the LF RF pulse generator. The controller controls the LF RF pulse generator to generate a plurality of square pulses that are interspersed with a plurality of square sub-pulses. Each of the plurality of square pulses has a first sub-pulse width that is greater than a second sub-pulse width of each of the plurality of square sub-pulses. To control the LF RF pulse generator, the controller controls the LF RF pulse generator to generate one of the plurality of square pulses. Further, to control the LF RF pulse generator, the controller determines whether a predetermined amount of time has passed since the LF RF pulse generator is controlled to generate the one of the plurality of square pulses. Also, to control the LF RF pulse generator, the controller controls the LF RF pulse generator to generate one of the plurality of square sub-pulses upon determining that the predetermined amount of time has passed.

Several advantages of the herein described systems and methods for controlling the LF RF pulse generator include providing an increase in the selectivity. By introducing sub-pulses in between pulses of a square pulse waveform generated by the LF RF generator, there is an increase in the selectivity. A number of low energy ions increases as a result of the sub-pulses. With the increase in the low-energy ions, the selectivity increases. Moreover, a combination of the pulses and the sub-pulses of the square pulse waveform provides a balance between achieving an etch rate and achieving the selectivity.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system for controlling a low frequency (LF) radio frequency (RF) pulse generator to increase selectivity.

FIG. 2A is a graph to illustrate an embodiment of a clock signal.

FIG. 2B is a graph to illustrate an embodiment of a square pulse waveform.

FIG. 2C is a graph to illustrate a square pulse waveform to provide an example of an increase in a peak value of each sub-pulse of the square pulse waveform with a decrease in a sub-pulse width.

FIG. 2D is a graph to illustrate a square pulse waveform to provide an example of a decrease in a peak value of each sub-pulse of the square pulse waveform with an increase in the sub-pulse width.

FIG. 3 is a block diagram of an embodiment of a system to illustrate a method for controlling the LF RF pulse generator.

FIG. 4 is a diagram of an embodiment of a system to illustrate a control of the LF RF pulse generator by processor of a controller.

FIG. 5 is a graph to illustrate that selectivity increases with an increase in voltage of the sub-pulses of the square pulse waveform.

FIG. 6 is a graph to illustrate that a voltage of a bottom plasma sheath changes with introduction of multiple sub-pulses of the square pulse waveform.

### DETAILED DESCRIPTION

The following embodiments describe systems and methods for controlling a low frequency (LF) radio frequency (RF) pulse generator to increase selectivity. It will be apparent that the present embodiments may be practiced without some or all of these specific details. In other instances, well known operations have not been described in detail in order not to unnecessarily obscure the present embodiments.

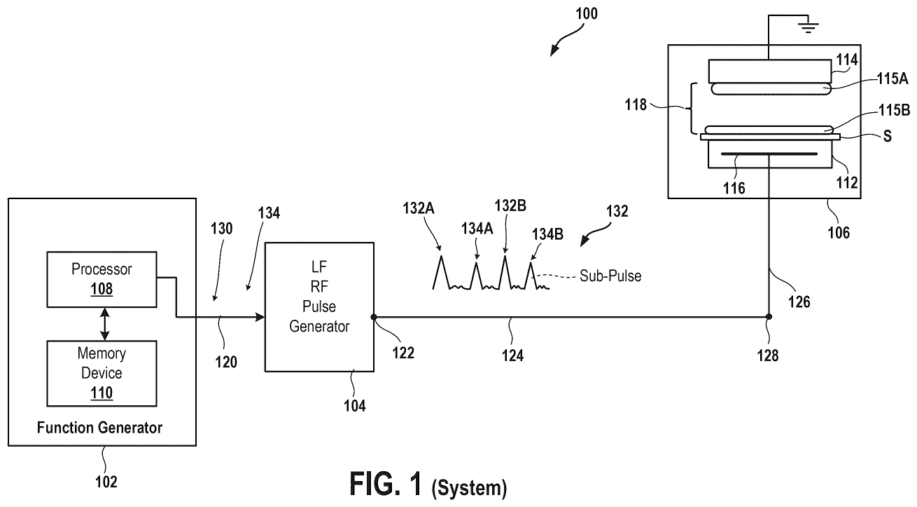

FIG. 1 is a diagram of an embodiment of a system 100 for controlling an LF RF pulse generator 104 to increase selectivity. The system 100 includes a function generator 102, the LF RF pulse generator 104, and a plasma chamber 106. Examples of the function generator 102 include a desktop computer, a laptop computer, a tablet, a smart phone, and a controller.

The function generator 102 includes a processor 108 and a memory device 110. As an example, the processor 108 can be an application specific integrated circuit (ASIC), a central processing unit (CPU), a field programmable gate array (FPGA), a programmable logic device (PLD), an integrated controller, or a microcontroller. Examples of the memory device 110 include a read-only memory (ROM) and a random access memory (RAM). To illustrate, the memory device 144 is a flash memory or a redundant array of independent discs (RAID). The processor 108 is coupled to the memory device 110.

An example of the LF RF pulse generator 104 is a machine that generates multiple high-voltage nanosecond pulses periodically. To illustrate, the LF RF pulse generator 104 is a nanosecond pulser. Each high-voltage nanosecond pulse is sometimes referred to herein as a pulse or a sub-pulse. Examples of low frequency include frequencies ranging from and including 10 kilohertz (kHz) to 800 kHz. To illustrate, the low frequency is a baseline frequency of 400 kHz. To further illustrate, a frequency of operation of the LF RF pulse generator 104 is 400 kHz. An example of a baseline frequency is a fundamental frequency.

The plasma chamber 106 includes a substrate support 112, such as an electrostatic chuck (ESC). The plasma chamber 106 further includes an upper electrode 114 that is located above the substrate support 112 to form a gap 118 between the upper electrode 114 and the substrate support 112. The upper electrode 114 faces the substrate support 112. A substrate S is placed on a top surface of the substrate support 112. Examples of the substrate S include a semiconductor wafer and a substrate stack. To illustrate, the substrate stack includes one or more layers, such as a mask layer, a metal layer, and an oxide layer.

A lower electrode 116, embedded within the substrate support 112, is made from a metal, such as aluminum or an alloy of aluminum. The substrate support 112 is made from the metal and from a ceramic, such as aluminum oxide (Al₂O₃). The upper electrode 114 is fabricated from the metal. An example of the plasma chamber 112 is a capacitively coupled plasma (CCP) chamber. The upper electrode 114 is coupled to a ground potential.

The processor 108 is coupled to the LF RF pulse generator 104 via a transfer cable 120 and an output 122 of the LF RF pulse generator 104 is coupled to the lower electrode 116 via an RF cable 122 and an RF transmission line 126. Examples of a transfer cable include a cable that allows for serial transfer of data, or a cable that allows for a parallel transfer of data, or a cable that allows for transfer of data using a Universal Serial Bus (USB) protocol. As an example, a control signal send from the processor 108 to the LF RF pulse generator 104 includes data or information. As an example, the RF cable 122 is a high voltage RF cable to facilitate a transfer of high-voltage nanosecond pulses. To illustrate, the RF cable 122 is a coaxial cable.

An example of an RF transmission line includes an RF rod that is surrounded by an RF tunnel, with an insulator between the RF rod and the RF tunnel. The RF rod, the RF tunnel, and the insulator are components of the RF transmission line. Another example of an RF transmission line includes a combination of one or more RF straps, an RF rod, an insulator, and an RF tunnel. In the example, the one or more RF straps are coupled to the RF rod. Also, in the example, the RF rod is surrounded by the insulator, which is surrounded by the RF tunnel.

As an example, there is no match between the LF RF pulse generator 104 and the plasma chamber 106. For example, there is no match between the RF cable 124 and the RF transmission line 126. Examples of a match include an impedance matching circuit or an impedance matching network. For example, the match is a series of circuit components, such as capacitors, inductors, and resistors. The circuit components are coupled to each other. To illustrate, two of the circuit components are coupled to each other in a series or in parallel. The match matches an impedance of a load, such as the plasma chamber 106, coupled to an output of the match with an impedance of a source coupled to an input of the match.

The processor 108 generates a recipe signal 130 and sends the recipe signal 130 via the transfer cable 120 the LF RF pulse generator 104. The recipe signal 130 includes information regarding a square pulse waveform 132. The square pulse waveform 132 is sometimes referred to herein as an interspersed waveform. The square pulse waveform 132 includes multiple pulses 132A and 132B that are interspersed with multiple sub-pulses 134A and 134B. For example, the sub-pulse 134A is located between two adjacent pulses 132A and 132B. The pulses 132A and 132B are adjacent in that there is no pulse between the two pulses 132A and 132B. As another example, the sub-pulse 134A immediately follows the pulse 132A. Also, the pulse 132B immediately follows the sub-pulse 134A and the sub-pulse 134B immediately follows the pulse 132B. The pulses of the square pulse waveform 132 are sometimes referred to herein as square pulses and the sub-pulses of the square pulse waveform 132 are sometimes referred to herein as square sub-pulses.

As an example, the square pulse waveform 132 is not a sinusoidal signal. In the example, an envelope, such as a power level, of the sinusoidal signal is constant or substantially constant. To illustrate, a power level of an envelope, such as a maximum amplitude, of the sinusoidal signal has power amounts within a predetermined range, such as within ±10% from each other. In the illustration, the square pulse waveform 132 has a different envelope for RF voltage ringings of the square pulse waveform 132 than an envelope of any pulse of the square pulse waveform 132 or an envelope of any sub-pulse of the square pulse waveform 132. To further illustrate, an envelope of an RF voltage ringing is less than 10% of an envelope of a pulse that precedes the RF voltage ringing. As yet another further illustration, the envelope of the pulse is greater than 100% of the envelope of the RF voltage ringing that immediately follows the pulse. As another further illustration, an envelope of an RF voltage ringing is less than 10% of an envelope of a sub-pulse that precedes the RF voltage ringing. As yet another further illustration, the envelope of the sub-pulse is greater than 100% of the envelope of the RF voltage ringing that immediately follows the sub-pulse. As another illustration, the sinusoidal signal does not have pulses with each pulse having a rectangular-shaped envelope and does not have sub-pulses with each sub-pulse having a rectangular-shaped envelope. Also, in the illustration, the sinusoidal signal does not have RF voltage ringing.

As an example, the information regarding the square pulse waveform 132 includes a first sub-pulse width (SPW) of each of the pulses, such as the pulses 132A and 132B, of the square pulse waveform 132, and includes a second sub-pulse width of each of the sub-pulses, such as the sub-pulses 134A and 134B, of the square pulse waveform 132. As an example, the second sub-pulse width is less than the first sub-pulse width. For example, the second sub-pulse width is less than the first sub-pulse width by at least 10%. To illustrate, the second sub-pulse width is less than the first sub-pulse width by a percentage between 10% and 90%. To further illustrate, the second sub-pulse width is between 10% and 90% of the first sub-pulse width. Moreover, the information includes a phase delay, such as a time period or a time interval, after which the first sub-pulse width is to be modified to the second sub-pulse width. To illustrate, the phase delay includes a time period for which RF voltage ringing that immediately follows the first sub-pulse width occurs. Moreover, the information regarding the square pulse waveform 132 includes a frequency of occurrences of the pulses, such as the pulses 132A and 132B, of the square pulse waveform 132.

The LF RF pulse generator 104 includes a controller, which includes a processor and a memory device. The processor of the LF RF pulse generator 104 is coupled to the memory device of the LF RF pulse generator 104. The processor of the LF RF pulse generator 104 receives the information regarding the square pulse waveform 132 from the processor 108 and stores the information in the memory device of the LF RF pulse generator 104.

In addition, the processor 130 generates a trigger signal 134 and sends the trigger signal 134 via the transfer cable 120 to the LF RF pulse generator 104. In response to receiving the trigger signal 134, the processor of the LF RF pulse generator 104 accesses the information regarding the square pulse waveform 132 from the memory device of the LF RF pulse generator 104, and controls signal components of the LF RF pulse generator 104 to generate the square pulse waveform 132 based on the information.

The square pulse waveform 132 is transferred via the RF cable 124 and the RF transmission line 126 to the lower electrode 116 to provide power to the lower electrode 116. In addition, when one or more process gases are supplied to the gap 118 in addition to the square pulse waveform 132, plasma is stricken or maintained within the gap 118 to process the substrate S. The plasma is bordered by a top plasma sheath 115A and a bottom plasma sheath 115B. The plasma processes a substrate S, such as a semiconductor wafer, that is placed on the substrate support 112. Examples of processing the substrate S include etching the substrate S, or depositing one or more material layers on the substrate S, or cleaning the substrate S, or sputtering the substrate S. Examples of the one or more process gases include an oxygen containing gas, a fluorine containing gas, and a combination thereof.

In an embodiment, the terms RF voltage ringing and RF ringing are used herein interchangeably. For example, RF ringing is sometimes referred to herein as RF voltage ringing.

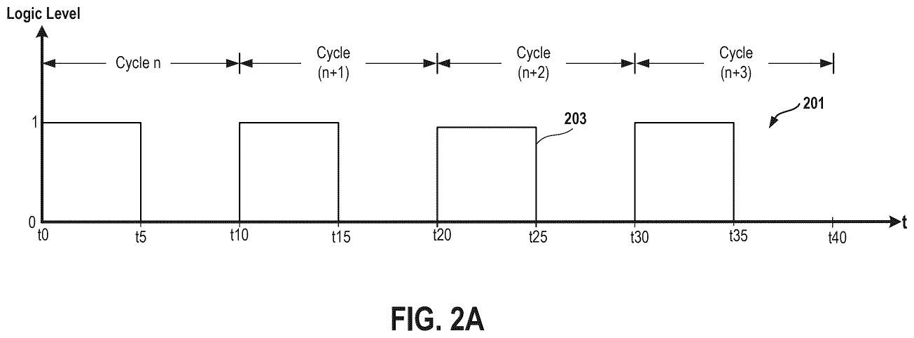

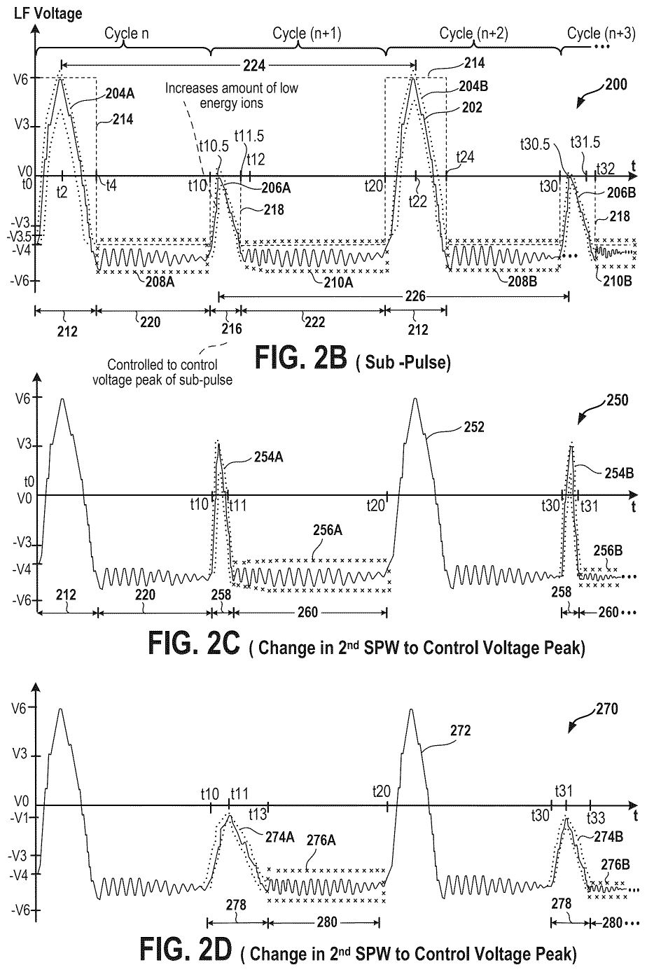

FIG. 2A is a graph 200 to illustrate an embodiment of a clock signal 202. The clock signal 202 is generated by the processor 108 (FIG. 1) and sent via the transfer cable 120 to the processor of the LF RF pulse generator 104 (FIG. 1). The processor of the LF RF pulse generator 104 controls the signal components of the LF RF pulse generator 104 in synchronization with the clock signal 202.

The graph 200 plots logic levels of the clock signal 202 versus time t. The logic levels are plotted on a y-axis of the graph 200 and the time t is plotted on an x-axis of the graph 200. The time t increases in a positive x-direction of the x-axis from a time t0 to a time t40. The time t progresses from the time t0 to the time t40. It should be noted that a time interval between two consecutive times on the x-axis of the graph 200 is equal to a time interval between any other two consecutive times on the x-axis. For example, a first time interval between the times t0 and t5 is equal to a second time interval between the times t5 and t10. As another example, a time interval between the times t0 and t1 is equal to a time interval between the times t1 and t2 and a time interval between the times t2 and t3.

The clock signal 202 periodically transitions between a logic level 1 and a logic level 0. For example, during a cycle n of the clock signal 202, the clock signal 202 is at the logic level 1 from a time t0 to a time t5, where n is an integer greater than zero. Also, during the cycle n, at the time t5, the clock signal 202 transitions from the logic level 1 to the logic level 0. Further, during the cycle n, the clock signal 202 remains at the logic level 0 from the time t5 to the time t10. The logic levels 1 and 0 repeat in this manner during a cycle (n+1) of the clock signal 202, a cycle (n+2) of the clock signal 202, and a cycle (n+3) of the clock signal 202.

It should be noted that as illustrated in the graph 201, each cycle of the clock signal 202 is also a cycle of the square pulse waveform 132 (FIG. 1). For example, the clock signal 202 and the square pulse waveform 132 are synchronized with each other. To illustrate, the cycle n of the clock signal 202 is also the cycle n of the square pulse waveform 132, the cycle (n+1) of the clock signal 202 is also the cycle (n+1) of the square pulse waveform 132, the cycle (n+2) of the clock signal 202 is also the cycle (n+2) of the square pulse waveform 132, and the cycle (n+3) of the clock signal 202 is also the cycle (n+3) of the square pulse waveform 132. To further illustrate, a pulse and a consecutively following RF voltage ringing of the square pulse waveform 132 repeat periodically to generate the cycles n, (n+2), and so on of the square pulse waveform 132, and sub-pulse and a consecutively following RF voltage ringing of the square pulse waveform 132 repeat periodically to generate the cycles (n+1), (n+3), and so on of the square pulse waveform 132.

FIG. 2B is a graph 200 to illustrate an embodiment of a square pulse waveform 202, which is an example of the square pulse waveform 132 (FIG. 1). The graph 200 plots voltage of the square pulse waveform 202 versus the time t. The voltage of the square pulse waveform 202 is plotted on a y-axis of the graph 200 and the time t is plotted on an x-axis of the graph 200. The x-axis of the graph 200 is the same as the x-axis of the graph 201 (FIG. 2A). The voltage ranges from a voltage value −V6 to a voltage value V6. For example, the voltage increases from −V6 to V6.

The square pulse waveform 202 has a series of pulses, such as a pulse 204A and a pulse 204B, that is interspersed with a series of sub-pulses, such as a sub-pulse 206A and a sub-pulse 206B. For example, the pulse 204A occurs from the time to to the time t4. In the example, RF voltage ringing 208A consecutively follows the pulse 204A. The RF voltage ringing 208A occurs from the time t4 to the time t10. An illustration of RF voltage ringing is noise. Continuing with the example, the sub-pulse 206A occurs from the time t10 to the time t12, and RF voltage ringing 210A immediately follows the sub-pulse 206A. The RF voltage ringing 210A occurs from the time t12 to the time t20. Moreover, in the example, the pulse 204B occurs immediately after the RF voltage ringing 210A. The pulse 204B occurs from the time t20 to the time t24. Also, in the example, RF voltage ringing 208B immediately follows the pulse 204B, and occurs from the time t24 to the time t30. The sub-pulse 206B occurs immediately after the RF voltage ringing 208B and occurs from the time t30 to the time t32. The sub-pulse 206B is immediately followed by RF voltage ringing 210B from the time t32 to the time t40.

The pulse 204A is an example of the pulse 132A and the pulse 204B is an example of the pulse 132B (FIG. 1). Each pulse, such as the pulse 204A and 204B, has a first sub-pulse width 212. An example of the first sub-pulse width 212 is a time interval or a time period. To illustrate, the first sub-pulse width 212 of the pulse 204A ranges from the time to to the time t4 and the first sub-pulse width 212 of the pulse 204B ranges from the time t20 to the time t24. At the time to, the pulse 204A has the voltage value −V4 and at the time t4, the pulse 204A has the voltage value −V4. The pulse 204A transitions upward from the voltage value −V4 to the voltage value V6 during a time interval from the time to to the time t2. The pulse 204A has the voltage value V6, which is a peak value, such as a maximum amplitude, of the pulse 204A. The pulse 204A further transitions down from the voltage value V6 to the voltage value −V4 during a time interval from the time t2 to the time t4. The pulse 204A is enclosed by an envelope 214, which is rectangular-shaped. Similarly, the pulse 204B transitions from the voltage value −V6 to the voltage value V4, which is a peak value, and transitions back down to the voltage value −V4. Also, the pulse 204B is enclosed by another instance of the envelope 214.

Also, the sub-pulse 206A is an example of the sub-pulse 134A and the sub-pulse 206B is an example of the sub-pulse 134B (FIG. 1). Each sub-pulse, such as the sub-pulse 206A and 206B, has a second sub-pulse width 216. An example of the second sub-pulse width 216 is a time interval or a time period. To illustrate, the second sub-pulse width 216 of the sub-pulse 206A ranges from the time t10 to the time t12 and the second sub-pulse width 216 of the sub-pulse 206A ranges from the time t30 to the time t32. At the time t10, the sub-pulse 206A has the voltage value −V4 and at the time t12, the sub-pulse 206A has the voltage value −V4. The sub-pulse 206A transitions upward from the voltage value −V4 to the voltage value V0 during a time interval from the time t10 to the time t10.5. The sub-pulse 206A has the voltage value V0, which is a peak value, such as a maximum amplitude, of the sub-pulse 206A. The sub-pulse 206A further transitions down from the voltage value V0 to the voltage value −V4 during a time interval from the time t10.5 to the time t11.5. The sub-pulse 206A is enclosed by an envelope 218, which is rectangular-shaped. Similarly, the sub-pulse 206B transitions from the voltage value −V4 to the voltage value V0, which is a peak value, and transitions back down to the voltage value −V4. Also, the sub-pulse 206B is enclosed by another instance of the envelope 218.

By controlling the first sub-pulse width 212, the envelope 214 becomes square-shaped or achieves a smaller rectangular shape. As an example, the first sub-pulse width 212 ranges from 10 nanoseconds (ns) to 500 ns and a rise time of each pulse of the square pulse waveform 202 is about 50 ns. To illustrate, each pulse of the square pulse waveform 202 has a rise time that ranges from 40 ns to 60 ns. When the envelope 214 changes to the square shape, each of the pulses 204A and 204B become square pulses, such as square-shaped pulses. It should also be noted that with the envelope 214, which is rectangular-shaped, the pulses 204A and 204B are sometimes referred to herein as square pulses.

Similarly, by controlling the second sub-pulse width 216, the envelope 218 becomes square-shaped or of a smaller rectangular shape. As an example, the second sub-pulse width 216 ranges from 5 ns to 250 ns and a rise time of each pulse of the square pulse waveform 202 is about 25 ns. To illustrate, each sub-pulse of the square pulse waveform 202 has a rise time that ranges from 20 ns to 30 ns. When the envelope 218 changes to the square shape, each of the sub-pulses 206A and 206B become square pulses, such as square-shaped pulses. It should also be noted that with the envelope 218, which is rectangular-shaped, the pulses 206A and 206B are sometimes referred to herein as square pulses.

Each RF voltage ringing, such as the RF voltage ringing 208A and the RF voltage ringing 208B, associated with a respective preceding pulse of the square pulse waveform 202 has a ringing width 220, which is greater than the first sub-pulse width 212. The ringing width 220 is a greater time interval than the first sub-pulse width 212. Each RF voltage ringing associated with the respective preceding pulse is a series of micro pulses and each micro pulse has a smaller amplitude than an amplitude of the preceding pulse. For example, a maximum amplitude of the pulse 204A is V6 and a maximum amplitude of the RF voltage ringing 208A is −V4. Also, each micro pulse of the RF voltage ringing associated with the respective preceding pulse has a smaller micro pulse width than the first sub-pulse width 212 of the preceding pulse. An example of a micro pulse width, as described herein, is a time interval of occurrence of a micro pulse of the square pulse waveform 202. An example of an amplitude, as described herein, is a maximum amplitude or a peak-to-peak amplitude.

Also, the micro pulse width of the RF voltage ringing associated with the respective preceding pulse is outside the range of the first sub-pulse width 212. For example, the micro pulse width is substantially less than the first sub-pulse width 212. As another example, the micro pulse width reduces with a progression of the RF voltage ringing 208A or 208B.

Similarly, each RF voltage ringing, such as the RF voltage ringing 210A and the RF voltage ringing 210B, associated with a respective preceding sub-pulse of the square pulse waveform 202 has a ringing width 222, which is greater than the second sub-pulse width 216. The ringing width 222 has a greater time interval than the second sub-pulse width 216. Each RF voltage ringing associated with the respective preceding sub-pulse is a series of micro pulses and each micro pulse has a smaller amplitude than an amplitude of the preceding sub-pulse. For example, a maximum amplitude of the sub-pulse 206A is V0 and a maximum amplitude of the RF voltage ringing 210A is −V3.5. Also, each micro pulse of the RF voltage ringing associated with the respective preceding sub-pulse has a smaller micro pulse width than the second sub-pulse width 216 of the preceding sub-pulse.

Also, the micro pulse width of the RF voltage ringing associated with the respective preceding sub-pulse is outside the range of the second sub-pulse width 216. For example, the micro pulse width is substantially less than the second sub-pulse width 216. As another example, the micro pulse width reduces with a progression of the RF voltage ringing 210A or 210B.

It should be noted that, as an example, the second sub-pulse width 216 is less than the first sub-pulse width 212. For example, the second sub-pulse width 216 is at least 10% lower than the first sub-pulse width 212. To illustrate, the second sub-pulse width 216 is 10% to 80% less than the first sub-pulse width 212.

The square pulse waveform 202 also has a pulse width 224, which is a width between maximum amplitudes of two consecutive pulses of the square pulse waveform 202. For example, the pulse width 224 is a time interval between the time t2 at which the pulse 204A has the voltage value V6 and the time t22 at which the consecutive or adjacent pulse 204B has the voltage value V6.

It should be noted that the pulse width 224 occurs between any two alternate ones of the cycles n, (n+1), (n+2) and (n+3). For example, the pulse width 224 between the cycles n and (n+2) is equal to the pulse width 224 between the cycle (n+2) and a cycle (n+4) (not shown) of the clock signal 201 (FIG. 2A). As another example, the pulse width 224 between the cycles n and (n+2) is within ±10% from the pulse width 224 between the cycles (n+2) and (n+4). The pulse width 224 provides the low frequency of the square pulse waveform 202. For example, the low frequency is an inverse of the pulse width 224.

It should also be noted that by controlling the first sub-pulse width 212, the ringing width 220, and the pulse width 224, a pulse width 226 is controlled. The pulse width 226 is a width between maximum amplitudes of two consecutive sub-pulses of the square pulse waveform 202. For example, the pulse width 226 is a time interval between the time t10.5 at which the sub-pulse 206A has the voltage value V0 and the time t30.5 at which the sub-pulse 206B has the voltage value V0. It should further be noted that the sub-pulses of the square pulse waveform 202 increase an amount of low energy ions of the plasma formed within the gap 118 (FIG. 1)

FIG. 2C is a graph 250 to illustrate a square pulse waveform 252 to provide an example of an increase in a peak value of each sub-pulse of the square pulse waveform 202 (FIG. 2A) with a decrease in the second sub-pulse width 216 (FIG. 2A). The square pulse waveform 252 is another example of the square pulse waveform 132 (FIG. 1). The graph 250 plots voltage of the square pulse waveform 252 versus the time t. The voltage of the square pulse waveform 252 is plotted on a y-axis of the graph 250 and the time t is plotted on an x-axis of the graph 250. The x-axis of the graph 250 is the same as the x-axis of the graph 201 (FIG. 2A) and the y-axis of the graph 250 is the same as the y-axis of the graph 200 (FIG. 2B).

The square pulse waveform 252 is the same as the square pulse waveform 202 (FIG. 2B) except that the square pulse waveform 252 has a smaller third sub-pulse width 258 compared to the second sub-pulse width 216. When the third sub-pulse width 258 is less than the second sub-pulse width 216, a peak voltage of sub-pulses, such as a sub-pulse 254A and a sub-pulse 254B, of the square pulse waveform 252 is greater than the peak voltage of the sub-pulses of the square pulse waveform 202. For example, the peak voltage of the sub-pulses of the square pulse waveform 252 is V3, which is greater than the peak voltage V0 of the sub-pulses of the square pulse waveform 202. The third sub-pulse width 258 is a time period for which each of the sub-pulses, such as the sub-pulse 254A and the sub-pulse 254B, of the square pulse waveform 252 occur.

The sub-pulse 254A extends from the time t10 to the time t11 and the sub-pulse 254B extends from the time t30 to the time t31. Also, at the time t10, the sub-pulse 254A has the voltage value −V4. The sub-pulse 254A transitions upward from the voltage value −V4 to the peak voltage V3. The upward transition occurs from the time t10 to the time t10.5, and the peak voltage V3 is achieved by the sub-pulse 254A at the time t10.5. The sub-pulse 254A transitions downward from the peak voltage to the voltage value −V4, which occurs at the time t11. The downward transition occurs from the time t10.5 to the time t11. Similarly, the sub-pulse 254B extends from the time t30 to the time t31 and achieves the peak voltage V3 at the time t30.5.

An RF voltage ringing, such as an RF voltage ringing 256A and an RF voltage ringing 256B, is associated with a respective preceding sub-pulse of the square pulse waveform 252. For example, each sub-pulse of the square pulse waveform 252 is immediately followed by RF voltage ringing. To illustrate, the sub-pulse 254A precedes RF voltage ringing 256A and the sub-pulse 254B precedes RF voltage ringing 256B.

It should be noted that a ringing width 260 of each RF voltage ringing associated with the respective preceding sub-pulse of the square pulse waveform 252 is greater than the ringing width 222 (FIG. 2B). When the third sub-pulse width 258 is less than the second sub-pulse width 216, the ringing width 260 is greater than the ringing width 222.

FIG. 2D is a graph 270 to illustrate a square pulse waveform 272 to provide an example of a decrease in a peak value of each sub-pulse of the square pulse waveform 202 (FIG. 2A) with an increase in the second sub-pulse width 216 (FIG. 2A). The square pulse waveform 272 is yet another example of the square pulse waveform 132 (FIG. 1). The graph 270 plots voltage of the square pulse waveform 272 versus the time t. The voltage of the square pulse waveform 272 is plotted on a y-axis of the graph 270 and the time t is plotted on an x-axis of the graph 270. The x-axis of the graph 270 is the same as the x-axis of the graph 201 (FIG. 2A) and the y-axis of the graph 270 is the same as the y-axis of the graph 200 (FIG. 2B).

The square pulse waveform 272 is the same as the square pulse waveform 202 (FIG. 2B) except that the square pulse waveform 272 has a greater fourth sub-pulse width 278 compared to the second sub-pulse width 216. When the fourth sub-pulse width 278 is greater than the second sub-pulse width 216, a peak voltage of sub-pulses, such as a sub-pulse 274A and a sub-pulse 274B, of the square pulse waveform 272 is lower than the peak voltage of the sub-pulses of the square pulse waveform 202. For example, the peak voltage of the sub-pulses of the square pulse waveform 272 is −V1, which is less than the peak voltage V0 of the sub-pulses of the square pulse waveform 202. The fourth sub-pulse width 272 is a time period for which each of the sub-pulses, such as the sub-pulse 274A and the sub-pulse 274B, of the square pulse waveform 272 occur.

The sub-pulse 274A extends from the time t10 to the time t13 and the sub-pulse 274B extends from the time t30 to the time t33. Also, at the time t10, the sub-pulse 274A has the voltage value −V4. The sub-pulse 274A transitions upward from the voltage value −V4 to the peak voltage −V1. The upward transition occurs from the time t10 to the time t11, and the peak voltage V1 is achieved by the sub-pulse 274A at the time t11. The sub-pulse 274A transitions downward from the peak voltage to the voltage value −V4, which occurs at the time t13. The downward transition occurs from the time t11 to the time t13. Similarly, the sub-pulse 274B extends from the time t30 to the time t33 and achieves the peak voltage −V1 at the time t31.

An RF voltage ringing, such as an RF voltage ringing 276A and an RF voltage ringing 276B, is associated with a respective preceding sub-pulse of the square pulse waveform 272. For example, each sub-pulse of the square pulse waveform 272 is immediately followed by RF voltage ringing. To illustrate, the sub-pulse 274A precedes RF voltage ringing 276A and the sub-pulse 274B precedes RF voltage ringing 276B.

It should be noted that a ringing width 280 of each RF voltage ringing associated with the respective preceding sub-pulse of the square pulse waveform 272 is less than the ringing width 222 (FIG. 2B). When the fourth sub-pulse width 278 is greater than the second sub-pulse width 216, the ringing width 280 is less than the ringing width 222.

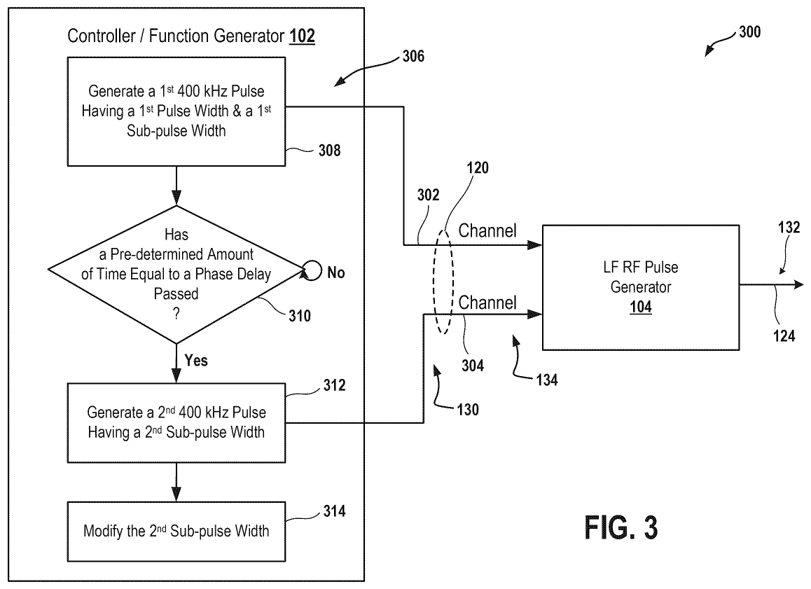

FIG. 3 is a block diagram of an embodiment of a system 300 to illustrate a method for controlling the LF RF pulse generator 104. The system 300 includes the controller 102 and the LF RF pulse generator 104. The transfer cable 120 includes a channel 302 and a channel 304. An example of a channel includes a logical connection, such as a frequency range, for transferring data. To illustrate, data sent via the channel 302 is multiplexed with data sent via the channel 304.

The processor 108 of the controller 102 executes a method 306 for controlling the LF RF pulse generator 104 to generate the square pulse waveform 132. The method 306 includes an operation 308 of producing one or more instructions for the LF RF pulse generator 104 to generate pulses, such as the pulse 204A and the pulse 204B (FIG. 2A), periodically at the low frequency to have the pulse width 224 (FIG. 2A). The one or more instructions of the operation 308 further indicate that each of the pulses such as the pulse 204A and the pulse 204B, is to be generated to have the first sub-pulse width 212 (FIG. 2A). For example, the one of more instructions of the operation 308 include a command for generating the pulse 204A having the first sub-pulse width 212. Also, in the example, the one or more instructions of the operation 308 include a command for generating the pulse 204B having the first sub-pulse width 212. In the example, the command for generating the pulse 204B is to generate the pulse 204B at a time of end of the pulse width 224. The pulse width 224 provides the period for generating the pulses of the square pulse waveform 132. As an example, the pulse width 224 and the first sub-pulse width 212 are received from a user via an input device, such as a mouse, a keyboard, a keypad, a touchscreen, a stylus, or a combination thereof. The input device is coupled to the processor 108 via an input/output interface.

The method 306 further includes an operation 310 of producing one or more instructions for the LF RF pulse generator 104 to wait for a predetermined amount of phase delay, such as the ringing width 220 (FIG. 2A), after generating each of the respective pulses, such as the pulse 204A or the pulse 204B, of the square pulse waveform 132. For example, the one or more instructions include a command to wait for the predetermined amount of phase delay after generating the pulse 204A and a command to wait for the predetermined amount of phase delay after generating the pulse 204B. The predetermined amount of phase delay is sometimes referred to herein as a predetermined amount of time.

The one or more instructions of the operation 310 include a command to determine whether the predetermined amount of phase delay has passed since each of the pulses of the square pulse waveform 132 is generated. If the predetermined amount of phase delay has not passed, the one or more instructions of the operation 310 include a command to wait for passage of the predetermined amount of phase delay. On the other hand, if the predetermined amount of phase delay has passed, the method 306 proceeds to an operation 312. As an example, the ringing width 220 is received from the user via the input device. As another example, the ringing width 220 is empirical data determined through experimentation.

The method 306 includes the operation 312 of producing one or more instructions for the LF RF pulse generator 104 to generate a respective one of the sub-pulses, such as the sub-pulse 206A (FIG. 2A) or the sub-pulse 206B, having the second sub-pulse width 216 (FIG. 2A) after the predetermined amount of phase delay has passed. The sub-pulses of the operation 312 are of the square pulse waveform 132. For example, the one or more instructions of the operation 312 include a command for generating the sub-pulse 206A at the predetermined amount of phase delay after the pulse 204A is generated. In the example, the one or more instructions of the operation 312 include a command for generating the sub-pulse 206B at the predetermined amount of phase delay after the pulse 204B is generated.

The instructions of the operations 308 and 310 are sent by the processor 108 via the channel 302 to the LF RF pulse generator 104 and the one or more instructions of the operation 312 are sent by the processor 108 via the channel 304 to the LF RF pulse generator 104. Upon receiving the instructions of the operations 308, 310, and 312, the processor of the LF RF pulse generator 104 stores the instructions and the information regarding the square pulse waveform 202 in the memory device of the LF RF pulse generator 104.

Upon receiving the trigger signal 134, the processor of the LF RF pulse generator 104 accesses the instructions of the operations 308, 310, and 312 and the information regarding the square pulse waveform 202 from the memory device of the LF RF pulse generator 104, and controls the signal components of the LF RF pulse generator 104 to generate the square pulse waveform 132 according to the instructions and the information regarding the square pulse waveform 202. The square pulse waveform 132 is sent from the signal components via the RF cable 124 for supply to the plasma chamber 106 (FIG. 1).

The method 306 includes an operation 314 of producing one or more instructions to modify the second sub-pulse width 216. For example the processor 108 generates a command to decrease the second sub-pulse width 216 to the third sub-pulse width 258 (FIG. 2C). As another example, the processor 108 generates a command to increase the second sub-pulse width 216 to the fourth sub-pulse width 278 (FIG. 2D). The one or more instructions of the operation 314 are produced when an input to modify the second sub-pulse width 216 is received from the input device. The input to modify the second sub-pulse width 216 is generated by the input device when the user makes one or more selections via the input device. The input received from the input device includes the second sub-pulse width 216 or the third sub-pulse width 258. The processor 108 sends the one or more instructions of the operation 314 via the channel 304 to the processor of the LF RF pulse generator 104. Upon receiving the one or more instructions of the operation 314, the LF RF pulse generator 104 modifies the second sub-pulse width 216 to another sub-pulse width, such as the third sub-pulse width 258 or the fourth sub-pulse width 278, to output another square pulse waveform, such as the square pulse waveform 252 (FIG. 2C) or the square pulse waveform 272 (FIG. 2D).

In an embodiment, the one or more instructions of the operation 308 are sent by the processor 108 via the channel 302 to the LF RF pulse generator 104 and the instructions of the operations 310 and 312 are sent by the processor 108 via the channel 304 to the LF RF pulse generator 104.

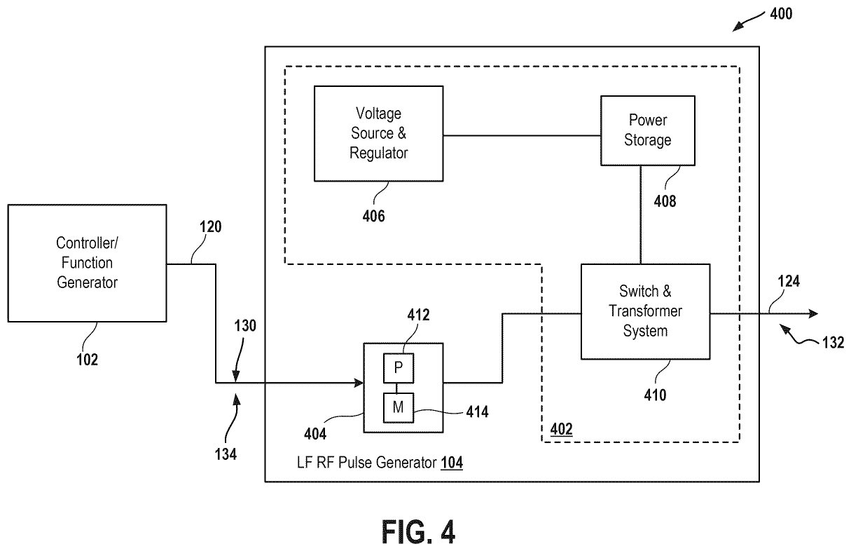

FIG. 4 is a diagram of an embodiment of a system 400 to illustrate a control of the LF RF pulse generator 104 by the processor 108 (FIG. 1) of the controller 102. The system 400 includes the controller 102 and the LF RF pulse generator 104. The LF RF pulse generator 104 includes signal components 402 and a controller 404. The signal components 402 include a voltage and source regulator 406, a power storage 408, and a switch and transformer system 410. As an example, RF voltage ringing, as described herein, is noise due to one or more of the signal components 402.

An example of the voltage source and regulator 302 includes a combination of a voltage supply, such as a direct current (DC) voltage supply, and a voltage regulator, such as a variable resistor. The voltage supply is coupled to the voltage regulator. An example of the switch and transformer system 410 includes a combination of a switch, such as a solid-state switch, and a transformer. An illustration of the solid-state switch is a transistor or a group of transistors. The solid-state switch is coupled to the transformer. As an example, the transformer includes a primary winding and a secondary winding. An example of the power storage 408 includes a capacitor.

The controller 404 includes a processor 412 and a memory device 414. The processor 412 is coupled to the memory device 414. As another example, the controller 404 is an ASIC or a PLD.

The processor 108 of the controller 102 is coupled to the processor 412 via the transfer cable 120. The processor 412 is coupled to the switch of the switch and transformer system 410. The voltage regulator of the voltage source and regulator 302 is coupled to the power storage 408.

Moreover, the power storage 408 is coupled to the transformer and the switch is coupled to the transformer. For example, the power storage 408 is coupled to a first end of the primary winding and the switch is coupled to a second end of the primary winding. The secondary winding of the transformer is coupled to the RF cable 138.

Upon receiving the instructions of the operations 308, 310, and 312, and the information regarding the square pulse waveform 202 within the recipe signal 130 from the processor 108, the processor 412 stores the instructions and the information within the memory device 414. The voltage supply generates a voltage signal and supplies the voltage signal to the voltage regulator. The voltage regulator regulates the voltage signal, such as maintains the voltage signal to match a predetermined voltage signal, to output a regulated voltage signal, and sends the regulated voltage signal to the power storage 408. The power storage 408 stores a charge according to the regulated voltage signal.

Moreover, in response to receiving the trigger signal 134 from the processor 108 of the controller 102, the processor 412 accesses the first sub-pulse width 212 (FIG. 2B) and the instructions of the operations 308 and 310 (FIG. 3) from the memory device 414. To control the signal components 402 according to the one or more instructions of the operation 308, the processor 412 generates an on command signal, and sends the on command signal to the switch. When the on command signal is received, the switch turns on and a switch current signal generated to discharge the charge stored in the power storage 408 is supplied to the primary winding of the transformer for the time period of the first sub-pulse width 212. The secondary winding transforms, such as increases or decreases, an amount of voltage of the switch current signal to a different amount to output a transformed amount of voltage to start generating the pulse 204A (FIG. 2B). The transformed amount of voltage is of the pulse 204A.

At the end of the time period of the first sub-pulse width 212, the processor 412 generates an off command signal, and sends the off command signal to the switch. Upon receiving the off command signal, the switch turns off and the supply of the switch current signal to the primary winding stops. When the supply of the switch current signal stops, the voltage applied by the switch current signal drops to reduce the voltage across the primary winding. When the voltage across the primary winding reduces, the transformed amount of voltage reduces to end the generation of the pulse 204A to output a reduced transformed amount of voltage. The reduced transformed amount of voltage is of the RF voltage ringing 208A (FIG. 2A).

To control the signal components 402 based on the one or more instructions of the operation 310, the processor 412 determines, based on timing provided by the clock signal 202, whether the predetermined amount of phase delay has occurred since the off command signal is sent from the processor 412 to the switch. Upon determining that the predetermined amount of phase delay has occurred, the processor 412 access the one or more instructions of the operation 312 and the second sub-pulse width 216 from the memory device 414 to control the signal components 402 based on the one or more instructions of the operation 312.

To control the signal components 402 based on the one or more instructions of the operation 312, the processor 412 generates an on command signal, and sends the on command signal to the switch. When the on command signal is received, the switch turns on and a switch current signal generated to discharge the charge stored in the power storage 408 is supplied to the primary winding of the transformer for the time period of the second sub-pulse width 216. The secondary winding transforms, such as increases or decreases, an amount of voltage of the switch current signal to a different amount to output a transformed amount of voltage to start generating the sub-pulse 206A (FIG. 2B). The transformed amount of voltage is a voltage of the sub-pulse 206A.

At the end of the time period of the second sub-pulse width 216, the processor 412 generates an off command signal, and sends the off command signal to the switch. Upon receiving the off command signal of the operation 312, the switch turns off and the supply of the switch current signal to the primary winding stops. When the supply of the switch current signal stops, the voltage applied by the switch current signal drops to reduce the voltage across the primary winding. When the voltage across the primary winding reduces, the transformed amount of voltage reduces to end the generation of the sub-pulse 206A to output a reduced transformed amount of voltage. The reduced transformed amount of voltage is of the RF voltage ringing 210A (FIG. 2A).

After sending the off command signal at the end of the time period of the second sub-pulse width, the processor 412 accesses the pulse width 224 from the memory device 414 and determines, based on the one or more instructions of the operation 308 and the pulse width 224, whether the time period of the pulse width 224 (FIG. 2B) has occurred after the on command signal for generating the pulse 204A is sent to the switch. Upon determining that the pulse width 224 has occurred since the on command for generating the pulse 204A is sent, the processor 412 determines to generate an on command signal for generating the pulse 204B (FIG. 2A). In this manner, the pulses and the sub-pulses of the square pulse waveform 202 repeat.

Moreover, upon receiving the one or more instructions of the operation 314 (FIG. 3) to modify the second sub-pulse width 216 to the other sub-pulse width, the processor 412 stores the other sub-pulse width within the memory device 414 and determines whether an end of RF voltage ringing associated with the respective preceding pulse has occurred. For example, the processor 412 determines, based on the clock signal 202, whether an end of the predetermined amount of phase delay of the ringing width 220 occurring immediately after the pulse 204B (FIG. 2B) has occurred. Upon determining that the end of the predetermined amount of phase delay of the ringing width 220 has occurred, the processor 412 accesses the other sub-pulse width from the memory device 414 and generates an on command signal and an off command signal based on the other sub-pulse width. The on and off command signals are generated in the same manner in which the on and off commands signals for generating the second sub-pulse width 216 are generated except that the off command signal for the other sub-pulse width is generated at an end of the time period of the other sub-pulse width.

In an embodiment, instead of producing the one or more instructions for generating the second sub-pulse width 216, one or more instructions for generating the other sub-pulse width, such as the third sub-pulse width 258 or the fourth sub-pulse width 278, are produced by the processor 108. The one or more instructions for generating the other sub-pulse width are sent from the processor 108 via the transfer cable 120 to the processor 412. The processor 412 generates an on command signal and an off command signal and controls the signal components 402 to generate a sub-pulse having the other sub-pulse width in the same manner in which the on and off command signals are applied to control the signal components 402 to generate each of the sub-pulses having the second sub-pulse width 216.

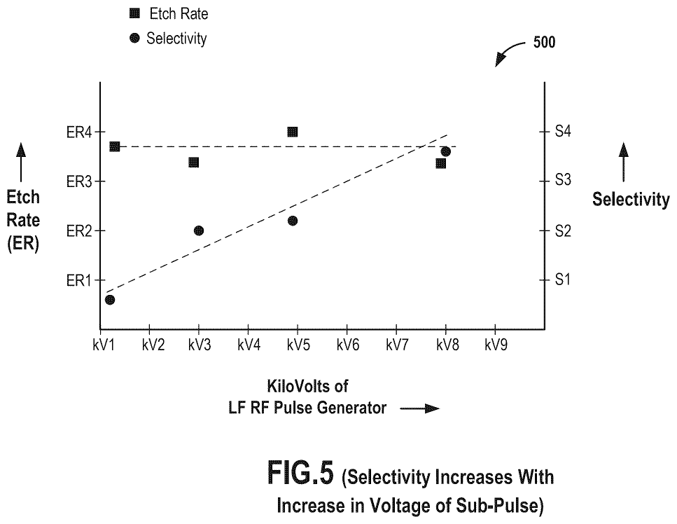

FIG. 5 is a graph 500 to illustrate that selectivity, such as mask selectivity, increases with an increase in voltage of the sub-pulses of the square pulse waveform 202 (FIG. 2B). An example of the mask selectivity is a ratio of a rate at which a mask layer of the substrate S is etched to a rate at which a layer of the substrate S desired to be etched or a feature of the substrate S desired to be etched is etched. The graph 500 plots etch rates of etching the substrate S (FIG. 1) on a first y-axis, the selectivity on a second y-axis, and kilovolts (kV) of the sub-pulses of the square pulse waveform 202. As illustrated in the graph 500, with an increase in the voltage, such as the peak voltage, of the sub-pulses of the square pulse waveform 202, there is an increase in the mask selectivity while a processing rate, such as an etch rate, remains nearly constant. In this manner, by increasing or decreasing the voltage of the sub-pulses of the square pulse waveform 202, the mask selectivity is controlled.

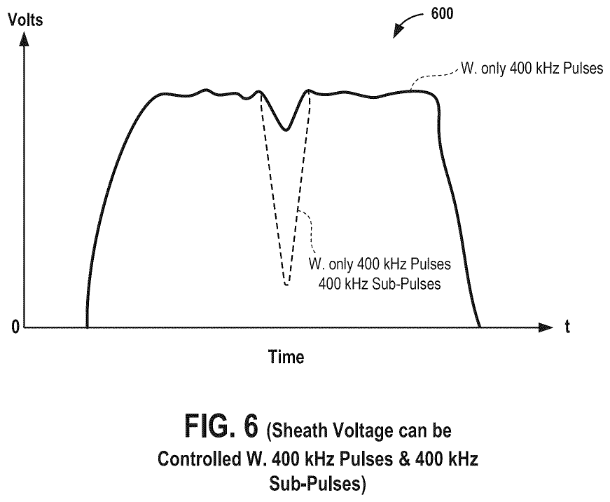

FIG. 6 is a graph 600 to illustrate that a voltage of the bottom plasma sheath 115B (FIG. 1) changes with introduction of the sub-pulses of the square pulse waveform 202 (FIG. 2B). The graph 600 plots the voltage of the bottom plasma sheath 115B versus the time t. When the sub-pulses of the square pulse waveform 202 are included in the square pulse waveform 202 in addition to the pulses of the square pulse waveform 202, there is a decrease in a voltage of the bottom plasma sheath 115B compared to when only the pulses are used in a square pulse waveform. As such, the voltage of the bottom plasma sheath 115B is controlled using the sub-pulses of the square pulse waveform 202.

It should be noted that although the above-embodiments are described with reference to a square pulse waveform, in some embodiments, the terms triangular pulse waveform, saw-tooth pulse waveform, and square pulse waveform are used herein interchangeably.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A method for controlling a low frequency (LF) radio frequency (RF) pulse generator to increase selectivity, comprising:
controlling the LF RF pulse generator to generate a plurality of square pulses that are interspersed with a plurality of square sub-pulses, wherein each of the plurality of square pulses has a first sub-pulse width that is greater than a second sub-pulse width of each of the plurality of square sub-pulses, wherein said controlling the LF RF pulse generator includes:
controlling the LF RF pulse generator to generate one of the plurality of square pulses;
determining whether a predetermined amount of time has passed since said controlling the LF RF pulse generator to generate the one of the plurality of square pulses; and
controlling the LF RF pulse generator to generate one of the plurality of square sub-pulses upon determining that the predetermined amount of time has passed,
wherein said controlling the LF RF pulse generator to generate the plurality of square sub-pulses increases the selectivity.

2. The method of claim 1, further comprising controlling the second sub-pulse width of each of the plurality of square sub-pulses to modify a peak voltage associated with said each of the plurality of square sub-pulses.

3. The method of claim 2, wherein said controlling the second sub-pulse width includes:
increasing the second sub-pulse width to increase the peak voltage; and
decreasing the second sub-pulse width to decrease the peak voltage.

4. The method of claim 1, wherein the one of the plurality of square sub-pulses is located between two adjacent ones of the plurality of square pulses for the plurality of square pulses to be interspersed with the plurality of square sub-pulses.

5. The method of claim 1, wherein the one of the plurality of square pulses is a first square pulse, wherein the plurality of square pulses includes a second square pulse, wherein the one of the plurality of square sub-pulses is a first square sub-pulse, wherein the plurality of square sub-pulses includes a second square sub-pulse,
wherein the first square pulse is followed by first RF ringing, the first RF ringing is followed by the first square sub-pulse, the first square sub-pulse is followed by second RF ringing, the second RF ringing is followed by the second square pulse, the second square pulse is followed by third RF ringing, the third RF ringing is followed by the second square sub-pulse, and the second square sub-pulse is followed by fourth RF ringing for the plurality of square pulses to be interspersed with the plurality of square sub-pulses.

6. The method of claim 1, wherein said controlling the LF RF pulse generator to generate the plurality of square pulses is performed by a controller that is coupled to the LF RF pulse generator.

7. The method of claim 1, wherein the plurality of square sub-pulses includes a first square sub-pulse and a second square sub-pulse, wherein the first square sub-pulse is followed by noise and the second RF sub-pulse is followed by noise.

8. The method of claim 1, wherein each of the plurality of pulses is not sinusoidal and each of the plurality of square sub-pulses is not sinusoidal.

9. A controller for controlling a low frequency (LF) radio frequency (RF) pulse generator to increase selectivity, comprising:
a processor configured to:
control the LF RF pulse generator to generate a plurality of square pulses that are interspersed with a plurality of square sub-pulses, wherein each of the plurality of square pulses has a first sub-pulse width that is greater than a second sub-pulse width of each of the plurality of square sub-pulses, wherein to control the LF RF pulse generator, the processor is configured to:
control the LF RF pulse generator to generate one of the plurality of square pulses;
determine whether a predetermined amount of time has passed since the LF RF pulse generator is controlled to generate the one of the plurality of square pulses; and
control the LF RF pulse generator to generate one of the plurality of square sub-pulses upon determining that the predetermined amount of time has passed; and
a memory device coupled to the processor.

10. The controller of claim 9, wherein the processor is configured to control the second sub-pulse width of each of the plurality of square sub-pulses to modify a peak voltage associated with said each of the plurality of square sub-pulses.

11. The controller of claim 10, to control the second sub-pulse width, the processor is configured to:
increase the second sub-pulse width to increase the peak voltage; and
decrease the second sub-pulse width to decrease the peak voltage.

12. The controller of claim 9, wherein the one of the plurality of square sub-pulses is located between two adjacent ones of the plurality of square pulses for the plurality of square pulses to be interspersed with the plurality of square sub-pulses.

13. The controller of claim 9, wherein the one of the plurality of square pulses is a first square pulse, wherein the plurality of square pulses includes a second square pulse, wherein the one of the plurality of square sub-pulses is a first square sub-pulse, wherein the plurality of square sub-pulses includes a second square sub-pulse,
wherein the first square pulse is followed by first RF ringing, the first RF ringing is followed by the first square sub-pulse, the first square sub-pulse is followed by second RF ringing, the second RF ringing is followed by the second square pulse, the second square pulse is followed by third RF ringing, the third RF ringing is followed by the second square sub-pulse, and the second square sub-pulse is followed by fourth RF ringing for the plurality of square pulses to be interspersed with the plurality of square sub-pulses.

14. The controller of claim 9, wherein the processor is coupled to the LF RF pulse generator via a transfer cable.

15. The controller of claim 9, wherein the plurality of square sub-pulses includes a first square sub-pulse and a second square sub-pulse, wherein the first square sub-pulse is followed by noise and the second RF sub-pulse is followed by noise.

16. The controller of claim 9, wherein each of the plurality of pulses is not sinusoidal and each of the plurality of square sub-pulses is not sinusoidal.

17. A plasma system comprising:
a low frequency (LF) radio frequency (RF) pulse generator;
a plasma chamber coupled to the LF RF pulse generator via an RF cable; and
a controller coupled to the LF RF pulse generator, wherein the controller is configured to:
control the LF RF pulse generator to generate a plurality of square pulses that are interspersed with a plurality of square sub-pulses, wherein each of the plurality of square pulses has a first sub-pulse width that is greater than a second sub-pulse width of each of the plurality of square sub-pulses, wherein to control the LF RF pulse generator, the controller is configured to:
control the LF RF pulse generator to generate one of the plurality of square pulses;
determine whether a predetermined amount of time has passed since the LF RF pulse generator is controlled to generate the one of the plurality of square pulses; and
control the LF RF pulse generator to generate one of the plurality of square sub-pulses upon determining that the predetermined amount of time has passed.

18. The plasma system of claim 17, wherein the LF RF pulse generator is coupled to the plasma chamber without using a match between the LF RF pulse generator and the plasma chamber.

19. The plasma system of claim 17, wherein the controller is configured to control the second sub-pulse width of each of the plurality of square sub-pulses to modify a peak voltage associated with said each of the plurality of square sub-pulses, wherein to control the second sub-pulse width, the controller is configured to:
increase the second sub-pulse width to increase the peak voltage; and
decrease the second sub-pulse width to decrease the peak voltage.

20. The plasma system of claim 17, wherein the one of the plurality of square pulses is a first square pulse, wherein the plurality of square pulses includes a second square pulse, wherein the one of the plurality of square sub-pulses is a first square sub-pulse, wherein the plurality of square sub-pulses includes a second square sub-pulse,
wherein the first square pulse is followed by first RF ringing, the first RF ringing is followed by the first square sub-pulse, the first square sub-pulse is followed by second RF ringing, the second RF ringing is followed by the second square pulse, the second square pulse is followed by third RF ringing, the third RF ringing is followed by the second square sub-pulse, and the second square sub-pulse is followed by fourth RF ringing for the plurality of square pulses to be interspersed with the plurality of square sub-pulses,
wherein each of the plurality of pulses is not sinusoidal and each of the plurality of square sub-pulses is not sinusoidal.
